(19) United States
(12) Patent Application Publication
(10) Pub. No.: US 2026/0200035 A1
(43) Pub. Date: Jul. 16, 2026

(54) WAFER POLISHING DEVICE

(71) Applicant: SAMSUNG ELECTRONICS CO., LTD., Suwon-si (KR)

(72) Inventors: Won Guk SEO, Suwon-si (KR); Boun YOON, Suwon-si (KR); Jinhan CHOI, Suwon-si (KR); Juno PARK, Suwon-si (KR); Ki Hoon JANG, Suwon-si (KR)

(73) Assignee: SAMSUNG ELECTRONICS CO., LTD., Suwon-si (KR)

(21) Appl. No.: 19/323,598

(22) Filed: Sep. 9, 2025

(30) Foreign Application Priority Data
Jan. 10, 2025 (KR) 10-2025-0004238

(51) Int. Cl. B24B 37/10; B24B 37/013; B24B 37/015; B24B 57/02

(52) U.S. Cl. CPC B24B 37/107; B24B 37/013; B24B 37/015; B24B 57/02

(57) ABSTRACT

Provided is a wafer polishing device including: a table configured to mount a wafer and to rotate the wafer; and a polisher spaced apart from a first surface of the wafer and configured to polish the first surface of the wafer by spraying a fluid toward the first surface of the wafer, wherein a length of the polisher is greater than a radius of the wafer.

### CROSS-REFERENCE TO RELATED APPLICATION

This application is based on and claims priority to Korean Patent Application No. 10-2025-0004238, filed with the Korean Intellectual Property Office on January 10, 2025, the entire contents of which are incorporated herein by reference.

### BACKGROUND

### Field

The present disclosure relates to a wafer polishing device.

### Description of Related Art

A chemical mechanical polishing (CMP) process for semiconductors is a process that flattens a surface of a wafer using a chemical reaction and a mechanical force.

In the CMP process, mechanical factors such as rotation speeds of a polishing pad and a wafer, a pressure applied to the wafer, and pattern directionality of the polishing pad, along with chemical influences such as an interaction between slurry polishing particles and a wafer surface, act as important variables.

In order to improve polishing quality in the CMP process, it is important to maintain a wide distribution of polishing particles across the entire polishing pad. This is because unevenly spread abrasives may cause scratches or defects on the wafer.

In order to secure performance of the polishing pad, a process of conditioning the polishing pad using a polishing pad conditioner is required.

When the polishing pad is not properly conditioned, there is a problem of uneven wear occurring on the polishing pad. However, even when the polishing pad is properly conditioned, the polishing pad is a consumable item and needs to be replaced after a certain period of time.

In this way, the conventional CMP process has problems in that defects occur on the wafer due to abrasives and a polishing degree of the wafer varies depending on a state of the polishing pad, and thus technique development is needed to address these problems.

### SUMMARY

Provided is a wafer polishing device including a table for mounting and rotating a wafer, and a polisher for spraying a fluid toward a polishing surface of the wafer while being spaced apart from the polishing surface of the wafer, to polish the wafer by controlling a pressure of the sprayed fluid without a separate abrasive, thereby preventing wafer scratches and defects caused by the abrasive.

Further provided is a wafer polishing device, capable of preventing uneven polishing of a wafer due to a difference in rotational speed at a contact surface between the wafer and a polishing pad in a conventional polishing process by maintaining a polisher in a state separated from the polishing surface of the wafer.

Further provided is a wafer polishing device with a structure that does not require a polishing pad, capable of solving a problem that a polishing speed and a wafer thickness distribution are affected by a condition of a conventional polishing pad.

According to an aspect of the disclosure, a wafer polishing device includes: a table configured to mount a wafer and to rotate the wafer; and a polisher spaced apart from a first surface of the wafer and configured to polish the first surface of the wafer by spraying a fluid toward the first surface of the wafer, wherein a length of the polisher is greater than a radius of the wafer.

According to an aspect of the disclosure, a wafer polishing device includes: a table configured to mount a wafer and to rotate the wafer; a polisher configured to polish a first surface of the wafer while being spaced apart from the first surface of the wafer; and a measurer configured to measure a thickness of the wafer.

According to an aspect of the disclosure, a wafer polishing device includes: a table including a first surface configured to mount a wafer; a temperature regulator configured to contact a second surface of the wafer; a rotation shaft configured to rotate the table; a polisher spaced apart from a first surface of the wafer, the polisher including a plurality of nozzles configured to spray fluid; a pressure controller configured to control a pressure of the fluid; a measurer configured to measure a thickness of the wafer; and a reactant supply configured to supply a reactant toward the first surface of the wafer.

According to one or more embodiments of the present disclosure, by adjusting a pressure of a fluid sprayed toward a polishing surface of a wafer without using a polishing pad and an abrasive, the wafer may be polished uniformly across the entire polishing surface while minimizing defects such as scratches on the wafer.

### BRIEF DESCRIPTION OF DRAWINGS

The above and other aspects and features of certain embodiments of the present disclosure will be more apparent from the following description taken in conjunction with the accompanying drawings, in which:

FIG. 1 illustrates a wafer polishing device according to an embodiment;

FIG. 2 illustrates a view for describing a temperature regulator in the wafer polishing device according to FIG. 1;

FIG. 3 illustrates a wafer polishing device according to another embodiment;

FIG. 4 illustrates a view for describing the wafer polishing device according to FIG. 3;

FIG. 5 illustrates a wafer polishing device according to another embodiment; and

FIG. 6 illustrates a view for describing the wafer polishing device according to FIG. 5.

### DETAILED DESCRIPTION

The present disclosure will be described more fully hereinafter with reference to the accompanying drawings, in which one or more embodiments of the disclosure are shown. As those skilled in the art would realize, the described embodiments may be modified in various different ways, all without departing from the spirit or scope of the present disclosure.

To clearly describe the present disclosure, parts that are irrelevant to the description in the drawings are omitted, and like numerals refer to like or similar constituent elements throughout the specification.

Further, since sizes and thicknesses of constituent members shown in the accompanying drawings are arbitrarily given for better understanding and ease of description, the present disclosure is not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

Throughout this specification and the claims that follow, when it is described that an element is “coupled/connected” to another element, the element may be “directly coupled/connected” to the other element or “indirectly coupled/connected” to the other element through a third element.

In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, plate, etc. is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

Further, throughout the specification, the phrase “in a plan view” means when an object portion is viewed from above, and the phrase “in a cross-sectional view” means when a cross-section taken by vertically cutting an object portion is viewed from the side.

Terms such as “unit”, “module”, “member”, and “block” may be embodied as hardware, software, or hardware and software. As used herein, a plurality of “units”, “modules”, “members”, and “blocks” may be implemented as a single component, or a single “unit”, “module”, “member”, and “block” may include a plurality of components.

As used herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, the disclosure is not be limited by these terms, and these terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

Equipment for performing a conventional CMP process has a structure in which a polishing pad is positioned on a platen, a head is positioned above the platen, and a wafer is mounted on the head.

As the head moves toward the platen, the wafer polishing surface is pressed against the polishing pad. In this state, the polishing pad and the wafer are rotated, and in this case, the wafer is polished while slurry is supplied between the polishing pad and the wafer polishing surface.

However, in the case of the conventional method, a problem of uneven rebound of the polishing pad occurs. To improve this, the process is being carried out by installing a retainer ring (R-ring), but this does not resolve the problem of wafer misalignment.

The slurry supplied toward the polishing pad must move between the polishing pad and the wafer via a periphery of the wafer. However, it is difficult to uniformly adjust an amount of slurry moved, and it is also difficult to secure a time that the slurry remains in a region where it comes into contact with the wafer. Additionally, there is a problem of scratches occurring on the wafer due to an abrasive in the slurry.

In addition, a method is being used to transfer heat to the wafer by positioning a heat regulator on a platen positioned under a head or polishing pad that has a wafer mounted thereon. However, due to the nature of heat transfer, there is a problem in that a temperature at a center of the wafer is high and the temperature inevitably decreases moving outward from the center of the wafer and toward the edge of the wafer.

In addition, the polishing pad is consumed during the polishing process, and there is also a problem that a polishing speed and thickness distribution are affected depending on a condition of the polishing pad.

There was a problem that a polishing degree of the wafer varied depending on the condition of the polishing pad, so the polishing pad was managed using a conditioner. However, the polishing pad and the conditioner are consumables, thus there is an inconvenience associated with having to replace them regularly.

Additionally, in the past, an end point detection (EPD) device was used to minimize over-polishing of wafers. The EPD device is a device that monitors a completion point of polishing, and is generally built into the platen and the polishing pad to measure the thickness of the wafer. However, the EPD device that rotates together with the polishing pad had a problem in that the resolution was reduced due to particles, slurry, abrasive, etc. positioned on the polishing pad.

A wafer polishing device 10 according to the present disclosure may be intended to ameliorate the conventional problems described above. Hereinafter, a wafer polishing device 10 according to an embodiment of the present disclosure will be described in more detail with reference to drawings

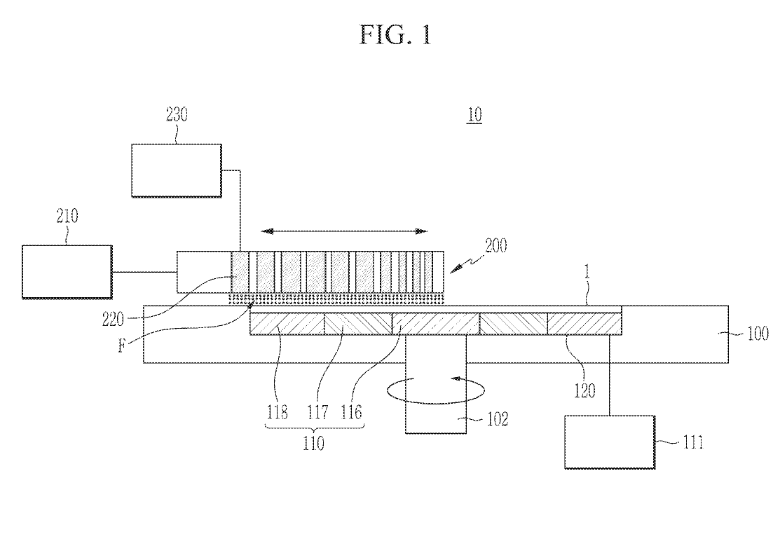

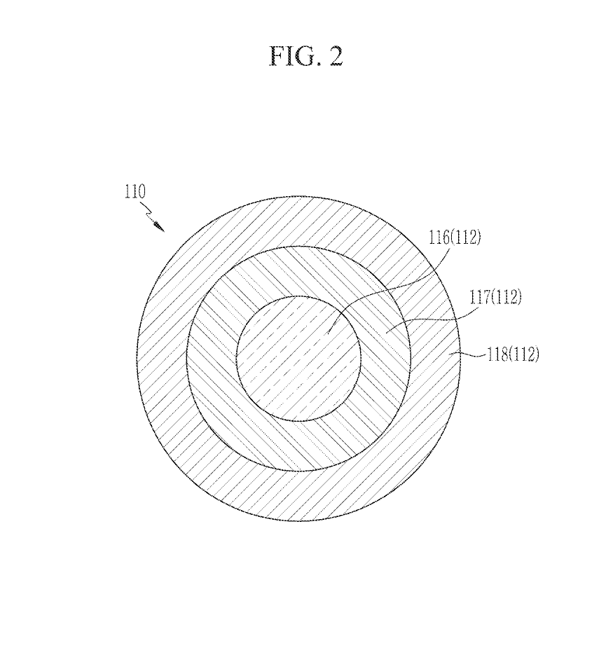

FIG. 1 illustrates a wafer polishing device according to an embodiment. FIG. 2 illustrates a view for describing a temperature regulator in the wafer polishing device according to FIG. 1.

As illustrated in FIG. 1, the wafer polishing device 10 according to an embodiment may include a table 100 and a polisher 200 spaced apart from the table 100.

The table 100 may mount the wafer 1 such that a first surface (polishing surface) of a wafer 1 is exposed, and the table 100 may rotate the wafer 1. The first surface of the wafer 1 may be positioned facing the polisher 200.

The table 100 may include a temperature regulator 110 positioned to contact a second surface of the wafer 1. The temperature regulator 110 may serve to increase the temperature of the wafer 1 or may serve to decrease the temperature of the wafer 1.

The wafer polishing device 10 may include a temperature controller 111 configured to control the temperature of the temperature regulator 110. The temperature controller 111 may operate a heater 112 or the cooler 114, or may operate the heater 112 and the cooler 114 together.

According to another embodiment, the temperature controller 111 may not only simply operate, but may also control temperatures of the heater 112 and the cooler 114.

The wafer polishing device 10 may include a rotation shaft 102 that rotates the table 100. As the table 100 rotates around the rotation shaft 102, the wafer 1 mounted on the table 100 may rotate along with it. Depending on a rotation speed of the rotation shaft 102, a rotation speed of the wafer 1 may be adjusted.

A first side of the table 100 may include a groove 120 in which the wafer 1 and the temperature regulator 110 are positioned.

According to another embodiment, a first side surface of the table 100 on which the wafer 1 and the temperature regulator 110 are positioned may be positioned on one plane. That is, when the wafer 1 and the temperature regulator 110 are positioned, a portion of the groove 120 may not be sunken or protruded, and a first side surface without the groove 120 and a first surface of the wafer 1 may be positioned on a same plane.

The polisher 200 may be positioned spaced apart from the first surface of the wafer 1, and may serve to polish the first surface of the wafer 1 by spraying a fluid F toward the first surface of the wafer 1. The fluid F sprayed from the polisher 200 may be sprayed at a high speed. Specifically, the fluid F may be sprayed at a high speed and collide with the first surface of the wafer 1, and during a collision process, the fluid F may clean contaminant particles existing on the wafer 1. As a collision speed of the fluid F is maximized, a cleaning power for the contaminant particles may be improved.

The polisher 200 may have a length that is greater than a radius of the wafer 1. As shown in FIG. 1, the polisher 200 may have a length that is greater than the radius of the wafer 1.

The polisher 200 illustrated in FIG. 1 may be structured so as to pass through a center of the wafer 1 and a periphery of the wafer 1. Alternatively, the structure may pass around a perimeter of the wafer 1 without passing through the center of the wafer 1. That is, the polisher 200 may be positioned so as to pass through at least one point between the center of the wafer 1 and an outer perimeter of the wafer 1.

The polisher 200 may move horizontally along a direction parallel to the first surface of the wafer 1, and may further include a driver 210 that moves the polisher 200 horizontally.

The polisher 200 may include a plurality of nozzles 220 that spray the fluid F. Specifically, a plurality of nozzles 220 directed toward the first surface of the wafer 1 may be arranged to be spaced apart from the first surface of the wafer 1. That is, no component of the polisher 200 may directly contact the first surface of the wafer 1. The nozzles 220 may be arranged at regular intervals or at irregular intervals.

According to another embodiment, the nozzles 220 may be arranged sequentially in a line shape. In this case, the sprayed fluid F may be sprayed in a curtain wall manner.

The wafer polishing device 10 may include a pressure controller 230 that controls a pressure of the fluid F sprayed from the nozzles 220.

According to another embodiment, the pressure controller 230 may independently control a pressure of each fluid F sprayed from the nozzles 220.

The pressure controller 230 may control the pressure of the fluid F differently depending on an area of the wafer 1. That is, a difference in angular velocity occurs in each area of the wafer 1 depending on rotation of the wafer 1, and by taking this into consideration, a degree of polishing may be adjusted differently for each area of the wafer 1.

In particular, when the wafer 1 is rotated and the wafer 1 is bent during the polishing process, a polishing intensity may be adjusted according to a shape of the wafer 1 by varying the pressure of the fluid F sprayed in each area. The fluid F may include at least one of a liquid, a gas, and a plasma.

As described above, in a process of polishing the wafer 1 using the wafer polishing device 10 according to the present disclosure, a polishing pad and slurry (abrasive) are unnecessary. Additionally, as the polishing pad is excluded, there is no need to include a conditioner, and there is no need for a cleaner module to clean the conditioner.

In this way, as equipment requiring regular maintenance is excluded, a time and a cost required for equipment maintenance and management may be saved. In addition, variables depending on a degree of consumption of consumables may be eliminated, which has an effect of improving variable precision. As a result, there is an advantage in maximizing wafer manufacturing yield and productivity by minimizing an overall process time required for polishing.

FIG. 2 illustrates the temperature regulator 110 positioned under the wafer 1 as viewed from above.

As illustrated in FIG. 2, the temperature regulator 110 may include a central portion 116 positioned to contact the center of the wafer 1, a peripheral portion 117 positioned to surround the central portion 116, and one or more outer portions 118 positioned to surround the peripheral portion 117.

The temperature regulator 110 illustrated in FIG. 2 has a structure in which heaters 112 for increasing the temperature of the wafer 1 are arranged in the central portion 116, the peripheral portion 117, and the outer portions 118.

In the temperature regulator 110 illustrated in FIG. 2, an embodiment having one outer portion 118 is illustrated. However, there may be more than one outer portion 118, and the areas of the central portion 116, the peripheral portion 117, and the outer portion 118 may be different from those in FIG. 2. The temperature regulator 110 is not limited to that shown in FIG. 2, and the heater 112 and the cooler 114 may be arranged in various combinations.

The wafer polishing device 10 according to the present disclosure may have a characteristic of high heat transfer efficiency in that a method of heating the wafer 1 is performed through a component (temperature regulator 110) that is in direct contact with the wafer 1.

Similarly, a method of lowering the temperature of the wafer 1 may also be highly efficient in heat transfer because it is done through a component (e.g., temperature regulator 110) that is in direct contact with the wafer 1.

This is a difference in effectiveness compared to the conventional technique that indirectly controlled the temperature of the wafer 1.

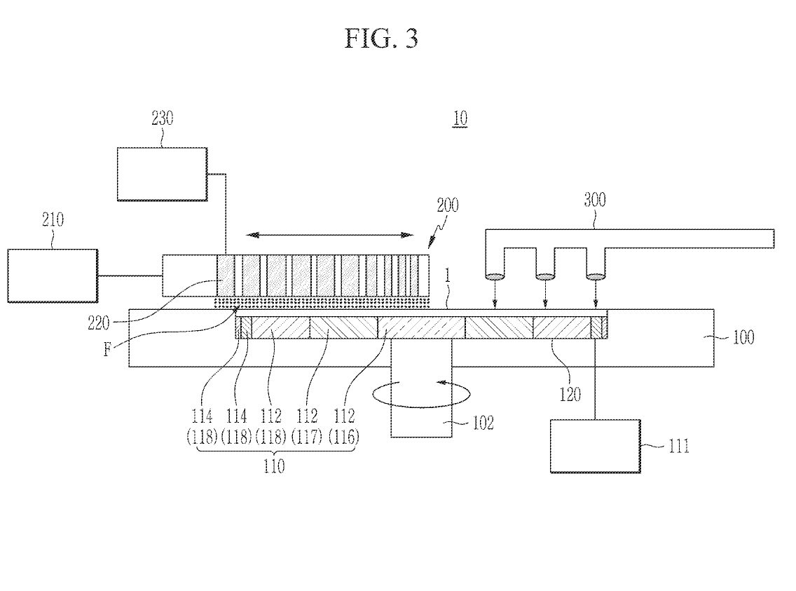

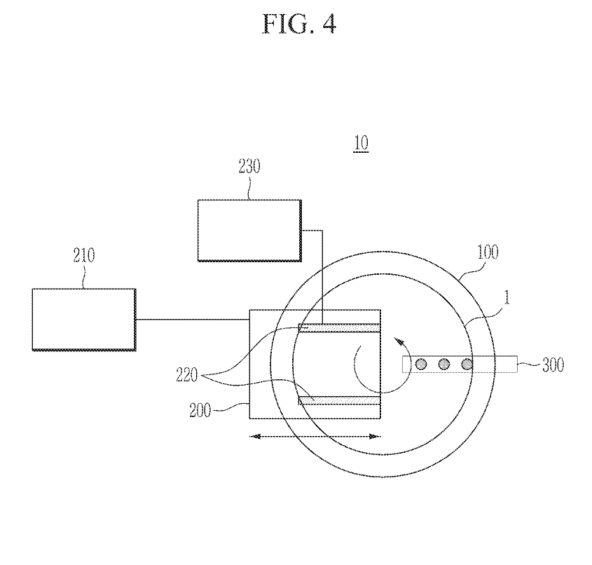

FIG. 3 illustrates a wafer polishing device according to another embodiment, and FIG. 4 illustrates the wafer polishing device 10 according to FIG. 3 as viewed from above.

As shown in FIGS. 3 and 4, the wafer polishing device 10 according to another embodiment may include a table 100 that rotates the wafer 1 while a wafer 1 is mounted such that a first surface of the wafer 1 is exposed, a polisher 200 that polishes the first surface of the wafer 1 while being spaced apart from the first surface of the wafer 1, and a measurer 300 that measures a thickness of the wafer 1.

A temperature regulator 110 may be positioned on the table 100. The temperature regulator 110 may include at least one of a heater 112 that increases a temperature of the wafer 1 and a cooler 114 that decreases the temperature of the wafer 1. The temperature regulator 110 illustrated in FIG. 3 may include a central portion 116, a peripheral portion 117, and three outer portions 118.

The heater 112 for increasing the temperature of the wafer 1 may be positioned in the central portion 116 and the peripheral portion 117. The heater 112 may be positioned in the outer portion 118 that is in contact with the peripheral portion 117, and the cooler 114 that lowers the temperature of the wafer 1 is positioned in other two outer portions 118.

In this way, temperature control for each area of the wafer 1 may be possible by arranging the temperature regulator 110 differently for each area of the wafer 1. Accordingly, compared to the wafer 1 mounted on the conventional polishing device, the wafer 1 mounted on the wafer polishing device 10 according to the present disclosure may have a higher temperature deviation.

Positions and combinations of the heater 112 and the cooler 114 positioned on the table 100 are not limited to those illustrated. In some cases, the cooler 114 may be positioned close to the center of the wafer 1, or the heater 112 and the cooler 114 may be positioned to intersect each other.

According to another embodiment, the heater 112 may be positioned on an entire area in contact with a second surface of the wafer 1, and the cooler 114 may be positioned at a lower end portion of the heater 112. Conversely, the cooler 114 may be positioned so as to contact the second surface of the wafer 1, and the heater 112 may be positioned at a lower end portion of the cooler 114.

In this case, when heating of the wafer 1 is required, the temperature controller 111 may control the heater 112 to generate heat. Additionally, when cooling is required for the wafer 1, the temperature controller 111 may control the cooler 114 to extract heat (i.e., provide cooling).

A plurality of polishers 200 may be arranged. An arrangement structure of the polishers 200 is not limited to that shown.

As illustrated in FIG. 3, the measurer 300 may be positioned so as to face a first surface of the wafer 1. The measurer 300 may serve to measure a thickness of the wafer 1. The measurer 300 may directly measure the thickness of the wafer 1 while being positioned close to a surface of the wafer 1.

Conventional EPD devices are built into a platen to measure a thickness of a wafer, but have a problem of reduced resolution due to particles, slurry, etc. positioned on the polishing pad. In contrast, the wafer polishing device 10 according to the present disclosure is different in that not only does it not use slurry, but also the measurer 300 is positioned close to the wafer 1 to measure the thickness of the wafer 1. Accordingly, when using the wafer polishing device 10 according to the present disclosure, thickness measurement resolution may be improved by more than 10 times (from 10 nm to 1 nm) compared to when using the conventional EPD device. That is, accuracy may be improved by more than 10 times.

Conventional EPD devices measure intensity through an optical window, but the measurer 300 in the wafer polishing device 10 may increase precision by directly measuring a distance to the wafer 1.

The measurer 300 may measure the thickness of the wafer 1 by measuring a change in distance to the first surface of the wafer 1. In addition, the measurer 300 may measure the thickness of the wafer 1 by using a degree of polarization of light being irradiated.

For example, the measurer 300 may utilize or include at least one of a contact voice coil, an induced current, a laser displacement sensor, and an optical interferometer. The optical interferometer may measure the thickness of the wafer 1 by projecting light toward the first surface of the wafer 1 and measuring an interference effect of the light.

According an embodiment, the measurer 300 may be spaced apart from the first surface of the wafer 1, and may be positioned in a straight line with the polisher 200 (see FIG. 4). As shown in FIG. 4, this may indicate that a longitudinal direction in which the polisher 200 is positioned and a longitudinal direction in which the measurer 300 is positioned may be positioned parallel to each other such that they become one direction. A plurality of sensors, etc. may be positioned on the measurer 300 having a length.

A type of the measurer 300 is not limited to the method described above, and may include various methods capable of measuring the thickness of the wafer 1.

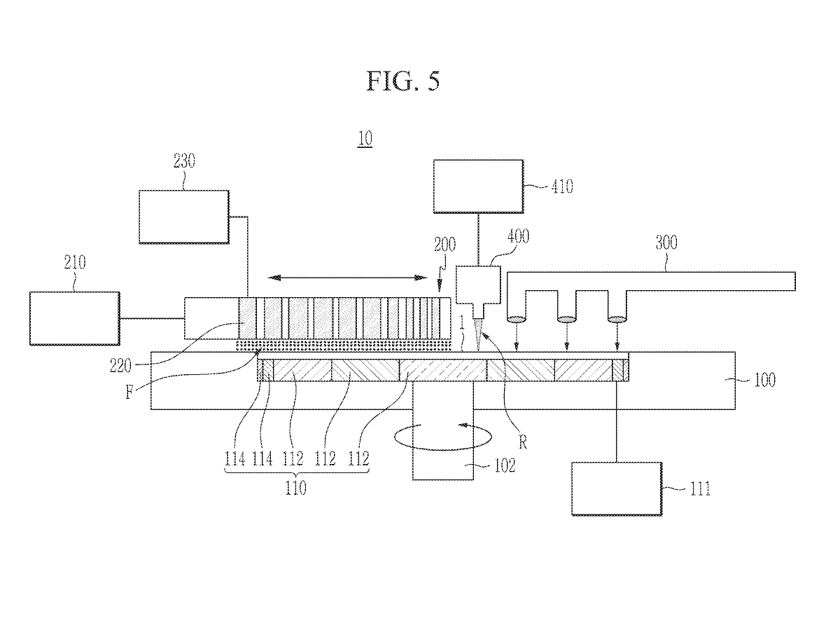

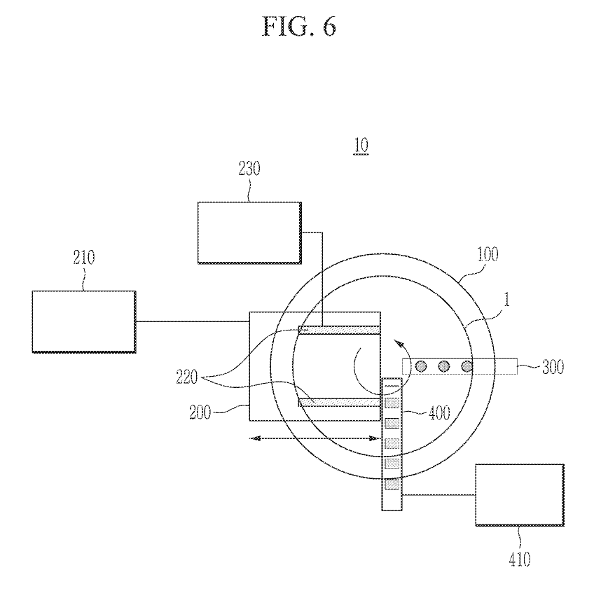

FIG. 5 illustrates a wafer polishing device according to another embodiment, and FIG. 6 illustrates the wafer polishing device 10 according to FIG. 5 as viewed from above.

As shown in FIGS. 5 and 6, the wafer polishing device 10 according to another embodiment may include a table 100, a polisher 200, a pressure controller 230, a measurer 300, and a reactant supply 400.

Specifically, the wafer polishing device 10 may include: the table 100 configured to mount the wafer 1 such that a first surface of the wafer 1 is exposed and include a temperature regulator 110 that is positioned to contact a second surface of the wafer 1; a rotation shaft 102 configured to rotate the table 100; the polisher 200 that is positioned spaced apart from the first surface of the wafer 1 and includes a plurality of nozzles 220 that spray fluid F; the pressure controller 230 configured to control a pressure of the fluid F; the measurer 300 configured to measure a thickness of the wafer 1; and a reactant supply 400 configured to supply a reactant R towards the first surface of the wafer 1.

The reactant R may include a chemical solution. When Cu and W are included in the wafer 1, an oxide film on the surface of the wafer 1 may be removed by supplying the reactant R onto the wafer 1, thereby increasing the polishing efficiency.

According to another embodiment, a reactant controller 410 for controlling a temperature of the reactant R may be included.

The table 100 may mount the wafer 1 such that a first surface (polishing surface) of the wafer 1 is exposed, and may rotate the wafer 1. A first surface of the mounted wafer 1 may be positioned to face the polisher 200. The table 100 may include the temperature regulator 110 positioned to contact a second surface of the wafer 1, and may include a temperature controller 111 that controls a temperature of the temperature regulator 110.

The polisher 200 may be positioned spaced apart from the first surface of the wafer 1, and may polish the first surface of the wafer 1 by spraying the fluid F toward the first surface of the wafer 1. The fluid F sprayed from the polisher 200 may be sprayed at a high speed.

The polisher 200 may move horizontally along a direction parallel to the first surface of the wafer 1. The polisher 200 may include the nozzles 220 that spray the fluid F.

The wafer polishing device 10 may include a pressure controller 230 that controls a pressure of the fluid F sprayed from the nozzles 220. The pressure controller 230 may independently control a pressure of each fluid F sprayed from the nozzles 220.

Other components of the wafer polishing device 10 according to the embodiment illustrated in FIGS. 5 and 6 overlap the components described in FIGS. 1 to 4, and accordingly, a detailed description thereof will be omitted.

In the wafer polishing device 10 according to the present disclosure, equipment (polishing pad, conditioner, and cleaner module) requiring regular maintenance may be excluded, so there is an effect of saving a time and a cost required for maintenance and management of the equipment. In addition, variables depending on a degree of consumption of consumables may be eliminated, which has an effect of improving variable precision.

In particular, a volume of equipment may be minimized (1/8 compared to conventional equipment) to increase integration and increase a unit per equipment hour (UPEH). That is, it has an effect of increasing a number of products produced per hour per facility on a corresponding line.

In addition, the temperature of the wafer 1 may be raised or lowered as needed during the polishing process through a component (e.g., temperature regulator 110) that is in direct contact with the wafer 1, so a heat transfer efficiency may be increased.

In addition, the wafer polishing device 10 according to the present disclosure may not only eliminate the use of slurry, but may also position the measurer 300 close to the wafer 1 to directly measure a thickness of the wafer 1, which in turn improve the thickness measurement resolution by more than 10 times compared to when using the conventional EPD device.

While this disclosure has been described in connection with one or more embodiments, it is to be understood that the disclosure is not limited to the disclosed embodiments, but, on the contrary, is intended to cover various modifications and equivalent arrangements included within the spirit and scope of the appended claims.

What is claimed is:

1. A wafer polishing device comprising:
a table configured to mount a wafer and to rotate the wafer; and
a polisher spaced apart from a first surface of the wafer and configured to polish the first surface of the wafer by spraying a fluid toward the first surface of the wafer,
wherein a length of the polisher is greater than a radius of the wafer.

2. The wafer polishing device of claim 1, wherein the table comprises a temperature regulator configured to contact a second surface of the wafer.

3. The wafer polishing device of claim 2, wherein the temperature regulator comprises at least one of a heater configured to increase a temperature of the wafer and a cooler configured to decrease the temperature of the wafer.

4. The wafer polishing device of claim 2, wherein the temperature regulator comprises:
a center portion in contact with a central portion of the wafer;
a peripheral portion surrounding the central portion; and
an outer portion surrounding the peripheral portion.

5. The wafer polishing device of claim 1, further comprising a reactant supply configured to supply a reactant toward the first surface of the wafer.

6. The wafer polishing device of claim 5, further comprising a reactant controller configured to control a temperature of the reactant.

7. The wafer polishing device of claim 1, wherein the polisher is configured to pass through at least one point between a center of the wafer and an outer circumference of the wafer.

8. The wafer polishing device of claim 1, wherein the polisher is movable along a direction that is parallel to the first surface of the wafer.

9. The wafer polishing device of claim 8, further comprising a driver configured to horizontally move the polisher.

10. The wafer polishing device of claim 1, wherein the polisher comprises a plurality of nozzles configured to spray the fluid.

11. The wafer polishing device of claim 10, further comprising a pressure controller configured to control a pressure of the fluid sprayed from the plurality of nozzles.

12. The wafer polishing device of claim 1, wherein the fluid comprises at least one of a liquid, a gas, or a plasma.

13. A wafer polishing device comprising:
a table configured to mount a wafer and to rotate the wafer;
a polisher configured to polish a first surface of the wafer while being spaced apart from the first surface of the wafer; and
a measurer configured to measure a thickness of the wafer.

14. The wafer polishing device of claim 13, wherein the measurer is configured to face the first surface of the wafer.

15. The wafer polishing device of claim 13, wherein the measurer is configured to measure the thickness of the wafer by measuring a change in distance between the measurer and the first surface of the wafer.

16. The wafer polishing device of claim 13, wherein the measurer is configured to measure the thickness of the wafer using polarized light.

17. A wafer polishing device comprising:
a table comprising a first surface configured to mount a wafer;
a temperature regulator configured to contact a second surface of the wafer;
a rotation shaft configured to rotate the table;
a polisher spaced apart from a first surface of the wafer, the polisher comprising a plurality of nozzles configured to spray fluid;
a pressure controller configured to control a pressure of the fluid;
a measurer configured to measure a thickness of the wafer; and
a reactant supply configured to supply a reactant toward the first surface of the wafer.

18. The wafer polishing device of claim 17, wherein the first surface of the table comprises a groove configured to receive the wafer, and
wherein the temperature regulator is in the groove.

19. The wafer polishing device of claim 17, further comprising a temperature controller configured to control a temperature of the temperature regulator.

20. The wafer polishing device of claim 17, wherein the pressure controller is further configured to independently control a pressure of the fluid sprayed from each of the plurality of nozzles.
